(19) United States
(12) Patent Application Publication
(10) Pub. No.: US 2024/0040794 A1
(43) Pub. Date: Feb. 1, 2024

(54) MEMORY DEVICE AND MANUFACTURING METHOD OF THE MEMORY DEVICE

(71) Applicant: SK hynix Inc., Icheon-si Gyeonggi-do (KR)

(72) Inventors: Sung Hyun YOON, Icheon-si Gyeonggi-do (KR); Dae Hyun KIM, Icheon-si Gyeonggi-do (KR)

(73) Assignee: SK hynix Inc., Icheon-si Gyeonggi-do (KR)

(21) Appl. No.: 18/088,342

(22) Filed: Dec. 23, 2022

(30) Foreign Application Priority Data
Aug. 1, 2022 (KR) 10-2022-0095614

(51) Int. Cl. H10B 51/20; H10B 51/10

(52) U.S. Cl. CPC H10B 51/20; H10B 51/10

(57) ABSTRACT

There are provided a memory device and a manufacturing method of the memory device. The memory device includes a stack structure that includes interlayer insulating layers and gate lines alternately stacked with each other. A data storage layer may be formed to vertically penetrate the stack structure. The data storage layer may include a plurality of ferroelectric layers. A channel layer may be formed to be surrounded by the data storage layer.

### CROSS-REFERENCE TO RELATED APPLICATION

The present application claims priority under 35 U.S.C. § 119(a) to Korean patent application number 10-2022-0095614, filed on Aug. 1, 2022, in the Korean Intellectual Property Office, the entire disclosure of which is incorporated herein by reference.

### BACKGROUND

### 1. Technical Field

The present disclosure generally relates to a memory device and a manufacturing method of the memory device, and more particularly, to a memory device including ferroelectric random access memory cells and a manufacturing method of the memory device.

### 2. Related Art

A memory device may be classified as a volatile memory device in which stored data disappears when power is interrupted or a nonvolatile memory device in which stored data is retained even when power is interrupted.

A nonvolatile memory device may be a NAND flash memory, a NOR flash memory, a resistive random access memory, a phase-change random access memory, a magnetoresistive random access memory, a ferroelectric random access memory, a spin transfer torque random access memory, and the like.

The ferroelectric random address memory (FRAM) cells may use material having ferroelectric characteristics for data storage layer(s). For example, domains may be formed in a grain of the data storage layer, and spontaneous polarization may occur in the domains. Therefore, when the size of the grain constituting the data storage layer is changed, the size of the domains may also be changed. When the size of the domain is changed, threshold voltage distribution of the FRAM cells may be changed.

### SUMMARY

Embodiments provide a memory device and a manufacturing method of the memory device, which can improve a threshold voltage distribution of ferroelectric random access memory cells.

In accordance with an aspect of the present disclosure, there is provided a memory device that includes a stack structure comprising interlayer insulating layers and gate lines that are alternately stacked with each other. A data storage layer may vertically penetrate the interlayer insulating layers and the gate lines of the stack structure. The data storage layer may include a plurality of ferroelectric layers. A channel layer may be surrounded by the data storage layer.

In accordance with another aspect of the present disclosure, there is provided a method of manufacturing a memory device. The method may include alternately stacking interlayer insulating layers and gate lines on a lower structure. The method may include forming a vertical hole that exposes side surfaces of the interlayer insulating layers and the gate lines while penetrating the interlayer insulating layers and the gate lines. The method may include forming a data storage layer that includes a plurality of ferroelectric layers in the vertical hole along the side surfaces of the interlayer insulating layers and the gate lines. The method may further include forming a channel layer along an inner side surface of the data storage layer.

In accordance with still another aspect of the present disclosure, there is provided a method of manufacturing a memory device. The method may include alternately stacking interlayer insulating layers and gate lines on a lower structure, and forming a vertical hole exposing side surfaces of the interlayer insulating layers and the gate lines while penetrating the interlayer insulating layers and the gate lines. The method may include forming a first ferroelectric layer along the exposed side surfaces of the interlayer insulating layers and the gate lines. The method may further include forming a crystal control layer along an inner side surface of the first ferroelectric layer and performing a first crystallization process for crystallizing the first ferroelectric layer. The method may include forming a second ferroelectric layer along an inner side surface of the crystal control layer and performing a second crystallization process to crystallize the second ferroelectric layer. The method may include forming a channel layer in a region surrounded by the crystallized second ferroelectric layer.

### BRIEF DESCRIPTION OF THE DRAWINGS

Example embodiments will now be described more fully with reference to the accompanying drawings. However, this disclosure should not be construed as being limited to the embodiments set forth herein. Rather, these example embodiments are provided to help explain this disclosure and to help convey the scope of this disclosure to those skilled in the art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating an example memory device in accordance with an embodiment of the present disclosure.

FIG. 2 is a view illustrating a structure of an example memory device in accordance with a first embodiment of the present disclosure.

FIGS. 3A and 3B are plan view illustrating example structures of memory cells in accordance with example embodiments of the present disclosure.

FIGS. 4A and 4B are diagrams illustrating grain sizes of the example memory cells in accordance with the present disclosure.

FIG. 5 is a diagram illustrating threshold voltages of the example memory cells in accordance with the present disclosure.

FIG. 6 is a diagram illustrating hysteresis curves of the example memory devices in accordance with the present disclosure.

FIG. 7 is a diagram illustrating threshold voltage distributions of the example memory devices in accordance with the present disclosure.

FIGS. 8A to 8H are views illustrating a manufacturing method of the example memory device in accordance with an embodiment of the present disclosure.

FIG. 9 is a view illustrating a structure of an example memory device in accordance with a second embodiment of the present disclosure.

FIGS. 10A to 10H are views illustrating a manufacturing method of the example memory device in accordance with the second embodiment of the present disclosure.

FIG. 11 is a view illustrating a structure of an example memory device in accordance with a third embodiment of the present disclosure.

FIGS. 12A to 12J are views illustrating a manufacturing method of the example memory device in accordance with the third embodiment of the present disclosure.

FIG. 13 is a diagram illustrating a Solid State Drive (SSD) system to which an example memory device of the present disclosure is applied.

FIG. 14 is a diagram illustrating a memory card system to which an example memory device of the present disclosure is applied.

### DETAILED DESCRIPTION

The specific structural or functional descriptions disclosed herein are merely illustrative for the purpose of describing embodiments according to the concept of the present disclosure. The embodiments according to the concept of the present disclosure can be implemented in various forms, and the disclosure cannot be construed as being limited to the embodiments set forth herein.

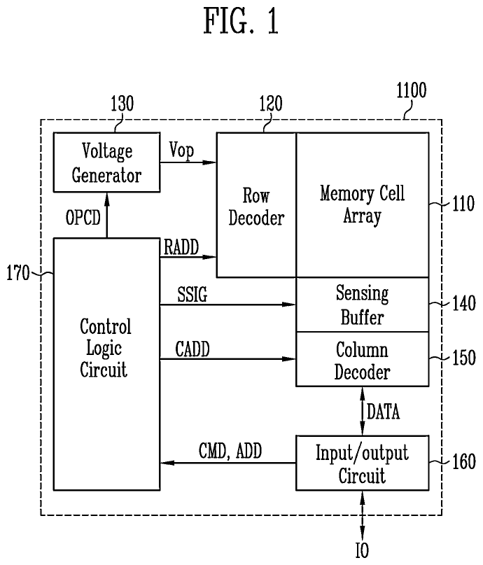

FIG. 1 is a diagram illustrating an example memory device in accordance with an embodiment of the present disclosure.

Referring to FIG. 1, the memory device 1100 may include a memory cell array 110 in which data is stored and peripheral circuits 120 to 170 capable of performing a program, read, or erase operation.

The memory cell array 110 may include a plurality of memory blocks in which data is stored. Each of the memory blocks may include ferroelectric random access memory (FRAM) cells. The FRAM cells may be implemented in a three-dimensional structure in which the FRAM cells are stacked in a vertical direction above a substrate. The FRAM cells may store data by using polarization that varies according to a voltage applied to an electrode. Although power may be interrupted, the FRAM cells may retain stored data by means of a spontaneous polarization characteristic.

The peripheral circuits 120 to 170 may include a row decoder 120, a voltage generator 130, a sensing buffer 140, a column decoder 150, an input/output circuit 160, and a control logic circuit 170.

The row decoder 120 may select, for example, one memory block in the memory cell array 110 according to a row address RADD, and transmit operating voltage Vop to the selected memory block. In some embodiments, the operating voltage Vop may have different voltage levels for different operations.

The voltage generator 130 may generate and output the operating voltage Vop necessary for various operations in response to an operation code OPCD.

The sensing buffer 140 may have sensing circuits that are connected to the memory cell array 110 through bit lines. The sensing circuits may operate in response to receiving sensing signals SSIG to temporarily store data in a program or read operation. During a read or verify operation, the sensing circuits may sense a voltage or current of the bit lines, which may vary according to a threshold voltage of the FRAM cells.

The column decoder 150 may transmit data DATA between the input/output circuit 160 and the sensing buffer 140 according to a column address CADD.

The input/output circuit 160 may be connected to an external device through input/output lines IO. For example, the external device may be a controller capable of transmitting a command CMD, an address ADD, or data DATA to the memory device 1100. The input/output circuit 160 may input/output a command CMD, an address ADD, and data DATA through the input/output lines IO. For example, the input/output circuit 160 may receive a command CMD, an address ADD, and data DATA from the external device through the input/output lines IO. The input/output circuit 160 may transmit the command CMD and the address ADD to the control logic circuit 170, and may transmit the data DATA to the column decoder 150 for a program operation. For a read operation, the input/output circuit 160 may output the data DATA received from the column decoder 150 to the external device through the input/output lines IO.

The control logic circuit 170 may output the operation code OPCD, the row address RADD, the sensing signals SSIG, and the column address CADD in response to the command CMD and the address ADD. For example, the control logic circuit 170 may include software and/or hardware for performing an algorithm in response to the command CMD and hardware for outputting the address ADD and various control signals.

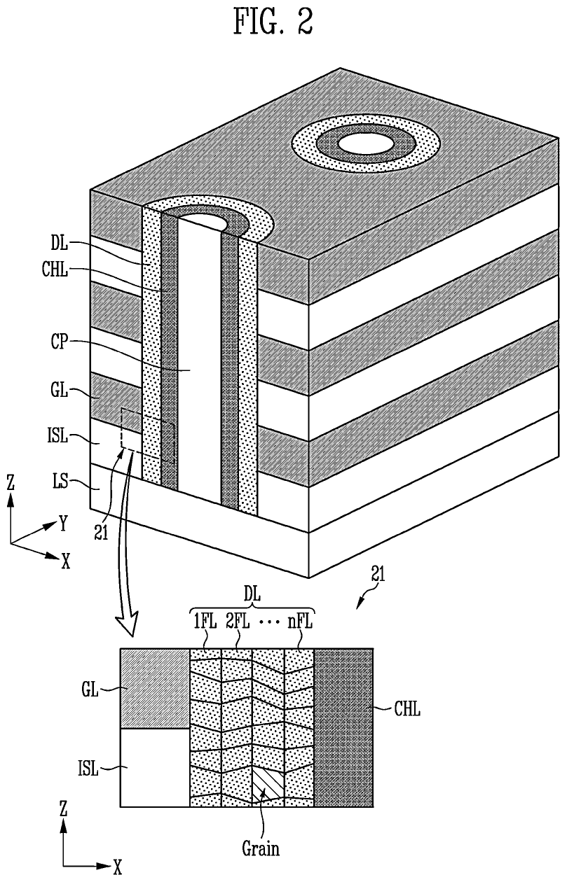

FIG. 2 is a view illustrating a structure of an example memory device in accordance with a first embodiment of the present disclosure.

Referring to FIG. 2, the memory device may include interlayer insulating layers ISL, gate lines GL, a data storage layer DL, a channel layer CHL, and a core pillar CP. The interlayer insulating layers ISL and the gate lines GL may be alternately stacked with each other on top of a lower structure LS, and the data storage layer DL, the channel layer CHL, and the core pillar CP may be configured to vertically penetrate the interlayer insulating layers ISL and the gate lines GL. The stack of the interlayer insulating layers ISL and the gate lines GL may be referred to as a stack structure. The lower structure LS may be, for example, a substrate, a source line, a peripheral circuit, etc.

The interlayer insulating layers ISL may be formed of insulating material such as, for example, an oxide layer or a silicon oxide layer, and the gate lines GL may be formed of a conductive layer or a metal layer. The interlayer insulating layers ISL may be configured to block electrical connection between the gate lines GL. Each of the gate lines GL may be an electrode connected to the data storage layer DL, and may be used as a word line or a select line. The gate lines GL may be formed of any one or more of conductive material such as, for example, tungsten (W), cobalt (Co), nickel (Ni), molybdenum (Mo), silicon (Si), poly silicon (poly-Si), etc.

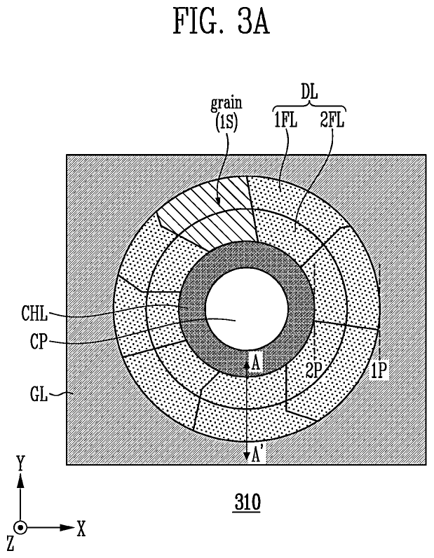

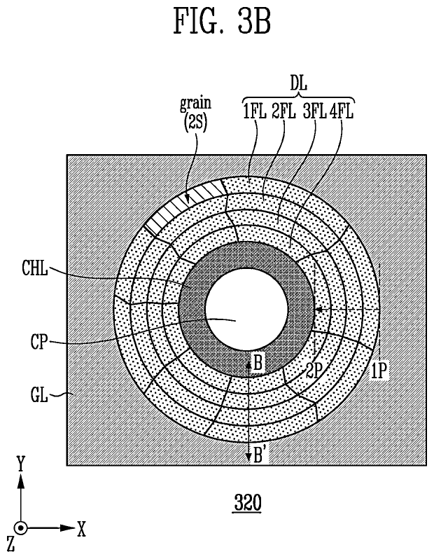

The data storage layer DL may be formed in a cylindrical shape vertically penetrating the interlayer insulating layers ISL and the gate lines GL. In accordance with a first embodiment, the data storage layer DL may include first to nth ferroelectric layers 1FL to nFL (n is a positive integer). The first to nth ferroelectric layers 1FL to nFL may not be formed through a continuous one-time deposition process, but may be formed through a plurality of deposition processes and crystallization processes. For example, after the first ferroelectric layer 1FL is formed, a crystallization process for crystallizing the first ferroelectric layer 1FL may be performed, the second ferroelectric layer 2FL may be formed after the crystallization process is performed, etc. In a deposition process for forming a ferroelectric layer, a source gas for forming the ferroelectric layer may be supplied to the inside of a chamber. In a crystallization process for crystallizing a ferroelectric layer, the supply of the source gas may be suspended, and the temperature inside the chamber may be increased. That is, each of the first to nth ferroelectric layers 1FL to nFL may be formed by performing a deposition process and then a crystallization process. Because grains are formed in each of the first to nth ferroelectric layers 1FL to nFL, the number of grains included in the data storage layer DL may increase as the number of ferroelectric layers increase, and the size of each grain may decrease as the thickness of the ferroelectric layers decreases. This effect can be seen with respect to FIGS. 3A and 3B.

The first to nth ferroelectric layers 1FL to nFL may be formed of a material(s) that is electrically polarized by an external electric field, but can maintain polarization even when there is no external electric field applied. This characteristic may be referred to as spontaneous polarization characteristic. Therefore, the data storage layer DL comprising the layers 1FL to nFL may store data by appropriately polarizing the first to nth ferroelectric layers 1FL to nFL. The first to nth ferroelectric layers 1FL to nFL may be formed of one or more materials having the spontaneous polarization characteristic such as, for example, PbZrTiO₃(PSZ), SrBi₂Ta₂O₉(STB), BiFeO₃(BFO), HfO₂, HfO₂ZrO₂(HZO), HfSiO₄(HSO), etc.

The channel layer CHL may be formed along the inner side surface of the data storage layer DL. The channel layer CHL may be formed of a conductive layer or a metal layer. For example, the channel layer CHL may be formed of silicon or poly-silicon. Although not shown in the drawing, each of a bit line and a source line may be connected to one of upper and lower portions of the channel layer CHL. For example, the bit line may be connected to the upper portion of the channel layer CHL and the source line may be connected to the lower portion of the channel layer CHL. Data may be stored by polarizing appropriate portions of the data storage layer DL with appropriate respective voltage applied to the bit line, the source line, and the gate line GL.

A partial region 21 of FIG. 2 is enlarged. The partial region 21 shows the data storage layer DL including the first to nth ferroelectric layers 1FL to nFL. The first to nth ferroelectric layers 1FL to nFL may not be formed by a continuous one-time deposition process, but may be formed through a plurality of deposition processes. Accordingly, different grains may be formed in the first to nth ferroelectric layers 1FL to nFL, and hence the size of each grain may decrease relative to when the data storage layer DL is formed with only one ferroelectric layer. Because polarization occurs in each grain, a threshold voltage distribution of FRAM cells can be more finely controlled as the grain size of the first to nth ferroelectric layers 1FL to nFL becomes smaller, and accordingly, the spontaneous polarization characteristic can be improved. Thus, the width of the threshold voltage distribution of the FRAM cells can be narrowed, and a retention characteristic can be improved.

FIGS. 3A and 3B are plan views illustrating example structures of memory cells in accordance with example embodiments of the present disclosure. Structures of a memory cell 310 and a memory cell 320 in accordance with embodiments of the present disclosure are illustrated in FIGS. 3A and 3B, respectively.

Referring to FIGS. 3A and 3B, when a data storage layer DL of the memory cell 310 is configured with first and second ferroelectric layers 1FL and 2FL which are formed in 1P to 2P direction, a grain of each of the ferroelectric layers may have a first size 15. When a data storage layer DL of the memory cell 320 is configured with first to fourth ferroelectric layers 1FL to 4FL, a grain of each of the first to fourth ferroelectric layers 1FL to 4FL may have a second size 2S smaller than the first size 15.

In the data storage layer DL of the memory cell 310 the ferroelectric layers may be formed by performing two deposition processes and two crystallization processes. Hence, two grains may exist between a gate line GL and a channel layer CHL on a section (A-A′) taken in the vertical direction. For example, a grain in the first ferroelectric layer 1FL and a grain in the second ferroelectric layer 2FL may be distinguished from each other.

Meanwhile, in the data storage layer DL of the memory cell 320 the first to fourth ferroelectric layers 1FL to 4FL may be formed in 1P to 2P direction by performing four deposition processes and four crystallization processes. Hence, four grains may exist between a gate line GL and a channel layer CHL on a section (B-B′) taken in the vertical direction. For example, a grain in each of the first ferroelectric layers 1FL to 4FL may be distinguished from each other. The process(es) of forming multiple ferroelectric layers may be generally referred to as sequentially forming the ferroelectric layers. For example, for the memory cell 320, after the first ferroelectric layer 1FL is formed, the second to fourth ferroelectric layers 2FL to 4FL may be said to be sequentially formed along an inner wall of the first ferroelectric layer 1FL.

Therefore, when assuming that the data storage layer DL of the memory cell 310 and the data storage layer DL of the memory cell 320 are formed with the same thickness, a size of each grain included in the data storage layer DL of the memory cell 320 is smaller than a size of each grain included in the data storage layer DL of the memory cell 310. In addition, the number of grains included in the data storage layer DL of the memory cell 320 is greater than the number of grains included in the data storage layer DL of the memory cell 310.

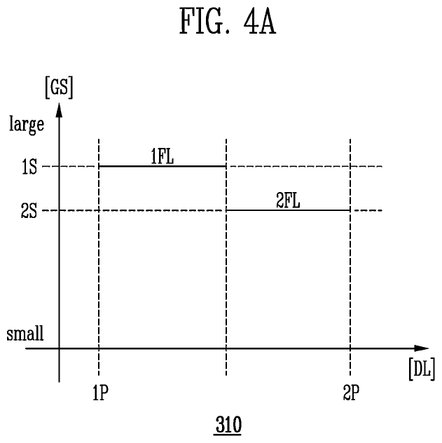

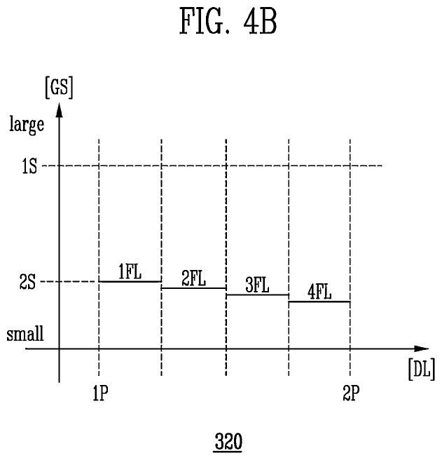

FIGS. 4A and 4B are diagrams illustrating grain sizes of the example memory cell in accordance with the present disclosure.

Referring to FIGS. 3A, 3B, and 4A, the grains may be in each of the first and second ferroelectric layers 1FL and 2FL in the data storage layer DL of the memory cell 310 between the gate line GL and the channel layer CHL. Generally, the grains may be said to each be approximately the first size 15. When assuming that the grain of the first ferroelectric layer 1FL has the first size 15, the grains of the second ferroelectric layer 2FL may have a size equal to or smaller than the first size 15. The grains in the first ferroelectric layer 1FL may not all have the same size, but they may have a size approximately similar to each other. Similarly, the grains in the second ferroelectric layer 2FL may not all have the same size, but they may have a size approximately similar to each other.

Referring to FIGS. 3A, 3B, and 4B, the grains in the data storage layer DL of the memory cell 320 formed in each of the first to fourth ferroelectric layers 1FL to 4FL between the gate line GL and the channel layer CHL may be said to have the second size 2S smaller than the first size 15. When assuming that the grain of the first ferroelectric layer 1FL among the first to fourth ferroelectric layers 1FL to 4FL has the second size 2S, the grains of the second to fourth ferroelectric layers 2FL to 4FL may have a size equal to or smaller than the second size 2S.

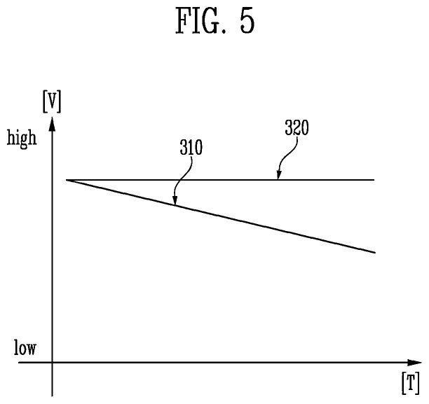

FIG. 5 is a diagram illustrating threshold voltages of the example memory cells in accordance with the present disclosure.

Referring to FIGS. 3A, 3B, and 5, because the data storage layer DL of the memory cell 310 has a relatively larger grain size and a relatively smaller number of grains compared to the data storage layer DL of the memory cell 320, a spontaneous polarization characteristic of the memory cell 310 may be relatively smaller compared to the memory cell 320.

Alternatively, because the data storage layer DL of the memory cell 320 has a relatively smaller grain size and a relatively larger number compared to the data storage layer DL of the memory cell 310, a spontaneous polarization characteristic of the memory cell 320 may be maintained for a relatively longer period of time compared to the memory cell 310. Accordingly, as shown in FIG. 5B, when the memory cell 320 is programmed, the spontaneous polarization characteristic of the programmed memory cell 320 may maintain a threshold voltage Vth even after a time T elapses. This may be compared with the spontaneous polarization characteristic of the programmed memory cell 310 where the threshold voltage Vth decreases as time passes after being programmed.

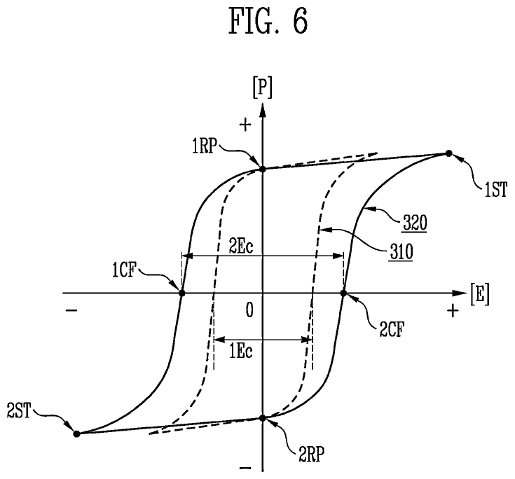

FIG. 6 is a diagram illustrating a hysteresis curve of an example memory device in accordance with the present disclosure.

Referring to FIGS. 3A, 3B, and 6, hysteresis is a phenomenon in which, when a material responds to an external stimulus, the material is influenced by not only by the intensity of the external stimulus but also a current state or a past external stimulus history of the material. A hysteresis curve in a FRAM device is a curve in which magnetization is changed according to the level of a voltage applied to an electrode. This is also referred to as a ‘self-hysteresis curve.’ The voltage may result in an electric field E. For ease of explanation, voltage and electric field are used interchangeably.

For example, polarization P becomes 0 in an initial state with no voltage applied to a FRAM (i.e., E=0). When a positive voltage is applied to the FRAM in which the polarization P is 0, the polarization P may increase, thereby becoming saturated. The saturation state caused by the positive voltage is defined as a first saturation state 1ST, and spontaneous polarization may occur in the first saturation state 1ST. When the voltage to the FRAM in the first saturation state 1ST is suspended, the polarization becomes lower. The polarization P does not return to 0 but may maintain a specific non-zero value. The polarization P when voltage (or the electric field E) is zero is referred to as remanent polarization. The remanent polarization maintained after the first saturation state 1ST is defined as first remanent polarization 1RP.

When a negative voltage is applied to the FRAM in the first remanent polarization 1RP state, the polarization P becomes lower. The voltage when the polarization P becomes 0 is referred to as a coercive field. The coercive field when the polarization P becomes zero is defined as a first coercive field 1CF. When a negative voltage lower than the first coercive field is further applied to the FRAM, the polarization P may become lower, and the FRAM may be at a second saturation state 2ST. In the second saturation state 2ST, spontaneous polarization may be in a direction opposite to the polarization in the first saturation state 1ST.

When the voltage to the FRAM in the second saturation state 2ST is suspended, the polarization P becomes higher. The polarization P of the FRAM may be maintained in a second remanent polarization 2RP state. When a positive voltage is applied to the FRAM in the second remanent polarization 2RP state, the polarization P may become higher. For example, as the polarization P of the FRAM becomes higher, the polarization P of the FRAM may increase to the first saturation state 1ST via a second coercive field 2CF.

As described above, the polarization P of the FRAM may vary according to the level of the voltage applied to the electrode. When no voltage is applied, the polarization P of the FRAM may be maintained at a constant level. Accordingly, FRAM may store data according to a characteristic of the polarization P.

In the memory cell 310, a voltage difference between the first coercive field 1CF and the second coercive field 2CF is a first voltage difference 1Ec. In the memory cell 320, the voltage difference between the first coercive field 1CF and the second coercive field 2CF is a second voltage difference 2Ec larger than the first voltage difference 1Ec. The voltage difference may be due to a difference in size of a grain in the data storage layer DL. For example, as the size of the grain becomes smaller, the voltage difference between the first coercive field 1CF and the second coercive field 2CF may increase. As the voltage difference between the first coercive field 1CF and the second coercive field 2CF increases, the threshold voltage distribution of memory cells may be improved to be larger. Thus, a threshold voltage distribution of the memory cell 320 can be larger than a threshold voltage distribution of the memory cell.

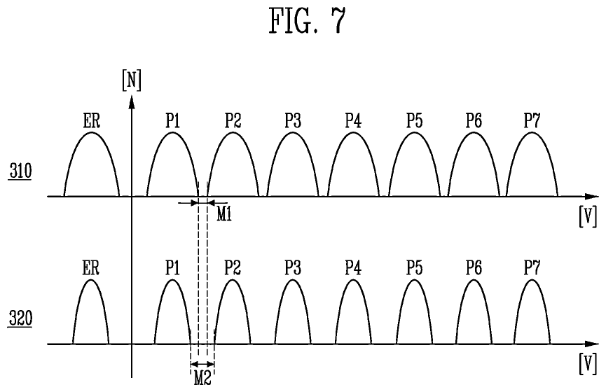

FIG. 7 is a diagram illustrating a threshold voltage distribution of an example memory device in accordance with the present disclosure.

Referring to FIGS. 3A, 3B, and 7, a difference in threshold voltage distribution may occur due to differences in size and number of grains in the data storage layer DL. In FIG. 7, the X axis indicates the threshold voltage V, and the Y axis indicates the number N of memory cells. As explained previously, the grain size of the memory cell 320 is smaller than the grain size of the memory cell 310, and the number of grains in the memory cell 320 is greater than the number of grains in the memory cell 310. Hence, the spontaneous polarization characteristic of the data storage layer DL for the memory cell 320 is improved over the memory cell 310. Therefore, when a margin between different threshold voltage distributions in the memory cell 310 has a first margin M1, a margin between different threshold voltage distributions in the memory cell 320 may have a second margin M2 larger than the first margin M1.

For example, in a program operation using a Triple Level Cell (TLC) in which 3-bit data can be stored in one memory cell, memory cells may be programmed to an erase state ER or to any state among first to seventh program states P1 to P7 according to a threshold voltage distribution. Threshold voltage distributions of programmed memory cells are to be maintained in an initial state. However, the threshold voltage distributions may be changed due to, for example, electrical leakage. Therefore, as the margin between adjacent erase/program states such as, for example, between the erase state ER and the first program state P1, becomes smaller, the probability that an error will occur in a read operation may be higher.

Because the margin between adjacent threshold voltages in the memory cell 320 is larger than the margin between adjacent threshold voltage distributions in the memory cell 310, the reliability of program and read operations is improved for the memory cell 320 versus the memory cell 310.

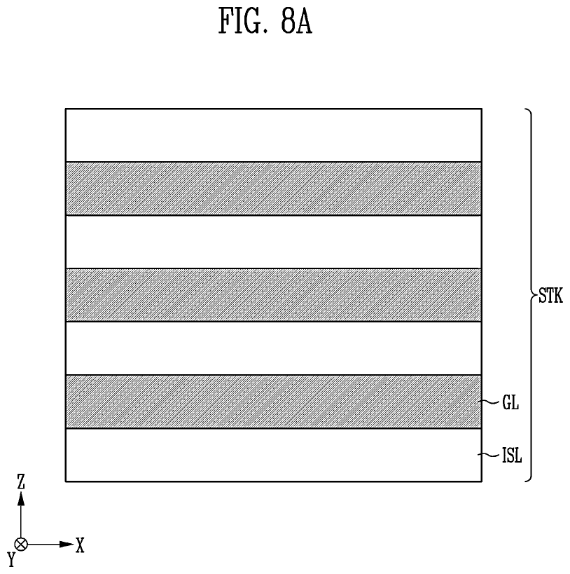

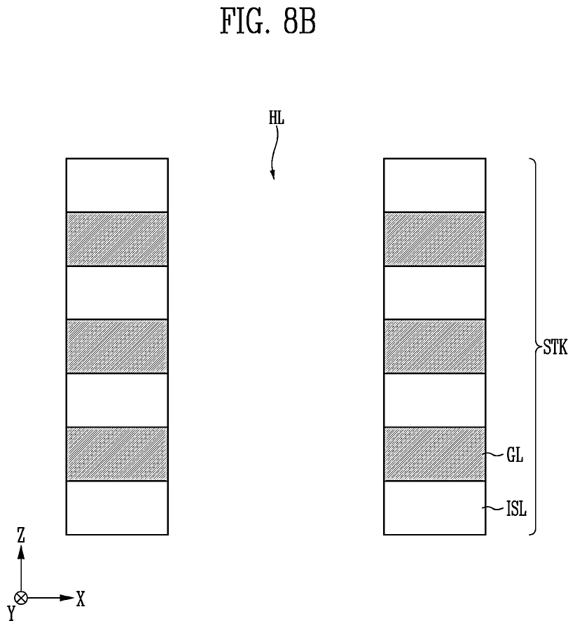

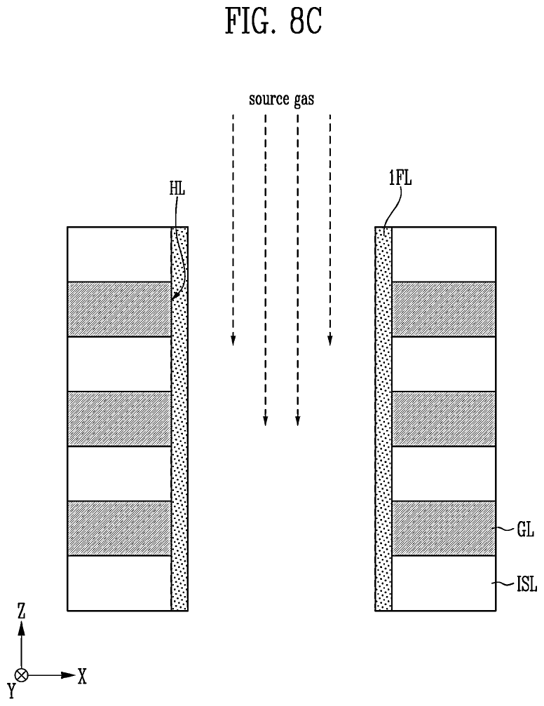

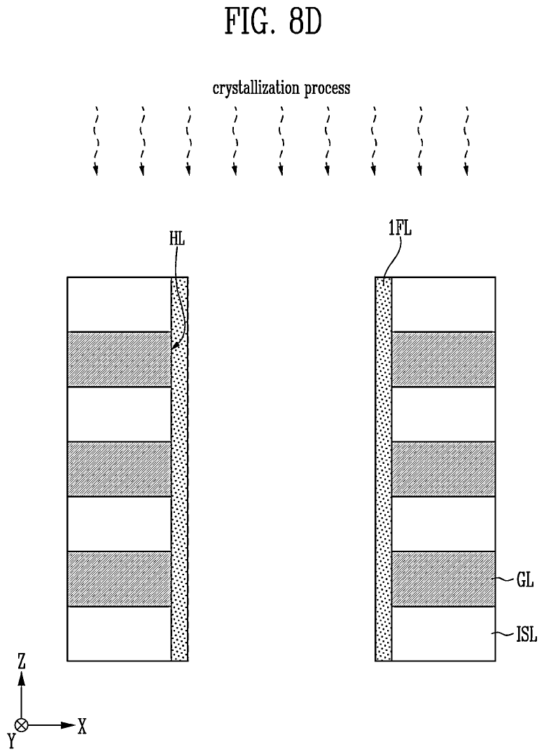

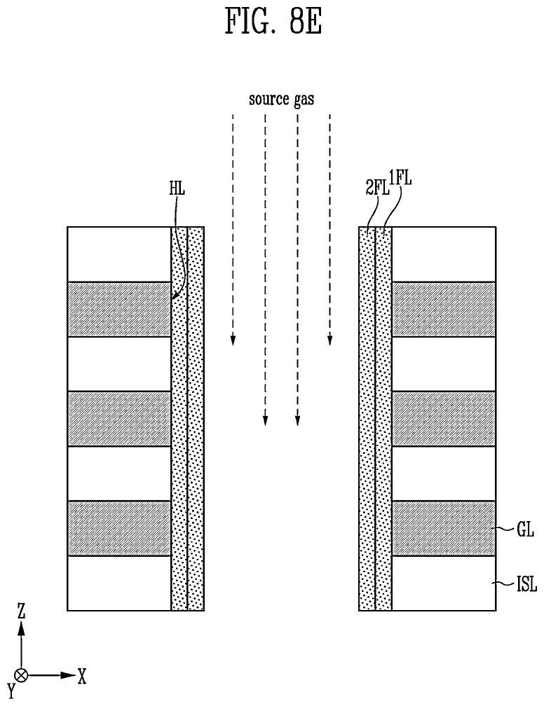

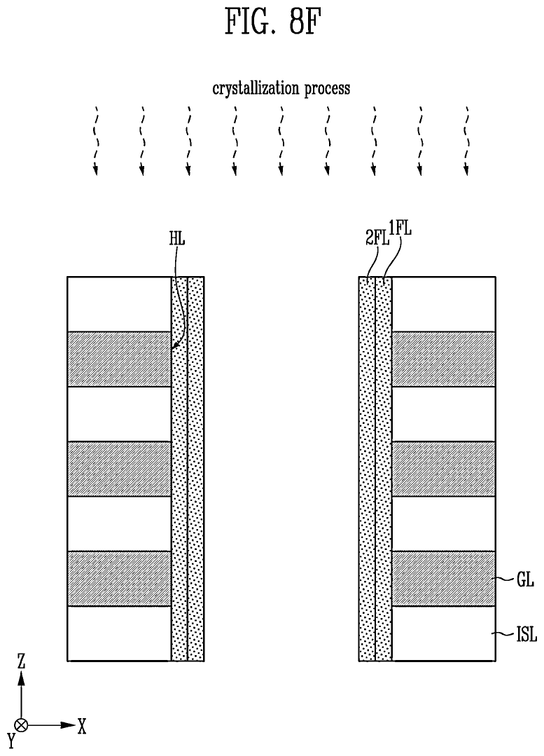

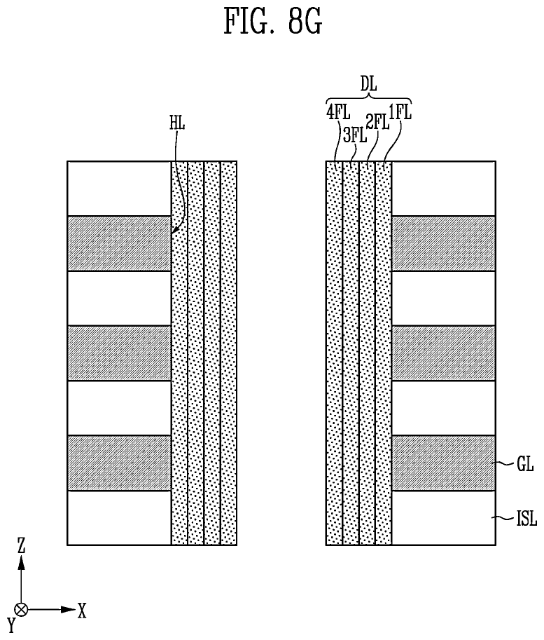

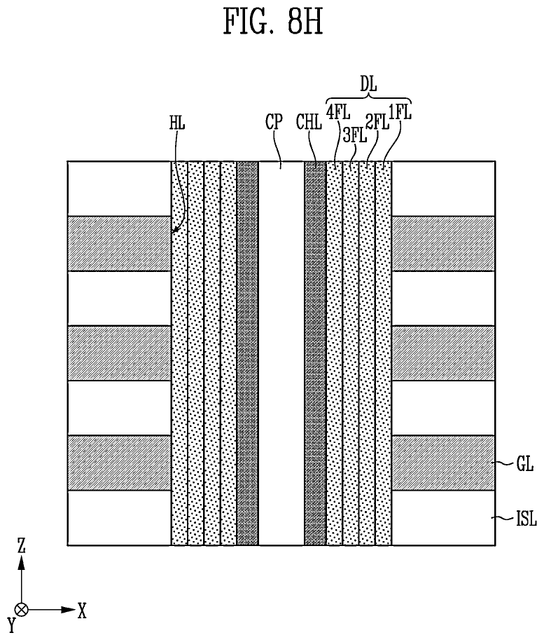

FIGS. 8A to 8H are views illustrating a manufacturing method of the example memory device in accordance with the first embodiment of the present disclosure.

Referring to FIG. 8A, a stack structure STK may be provided, in which interlayer insulating layers ISL and gate lines GL are alternately stacked. Although not shown in the drawing, the stack structure STK may be formed on top of a substrate or a peripheral circuit structure that includes the substrate. The interlayer insulating layers ISL may be configured to block electrical connection between the gate lines GL, and be formed of insulating material such as, for example, an oxide layer or a silicon oxide layer. The gate lines GL may be formed of a conductive layer or a metal layer. The gate lines GL may be formed of any one or more of conductive material such as, for example, tungsten (W), cobalt (Co), nickel (Ni), molybdenum (Mo), silicon (Si), poly silicon (poly-Si), etc.

Referring to FIG. 8B, an etching process for forming a vertical hole HL vertically penetrating the interlayer insulating layers ISL and the gate lines GL may be performed. The etching process may be a dry etching process such as, for example, an anisotropic dry etching process. When the vertical hole HL is formed, at least some or all of the interlayer insulating layers ISL and the gate lines GL may be exposed through the side surface of the vertical hole HL.

Referring to FIG. 8C, a deposition process may form a first ferroelectric layer 1FL for data storage layer DL on the interlayer insulating layers ISL and the gate lines GL. The deposition process may be, for example, an Atomic Layer Deposition (ALD) process, an Area Selective Deposition (ASD) process, or the like. In the ALD or ASD process, a thickness of a thin film may be determined according to how long a source gas is injected into a chamber. Therefore, the thickness of the first ferroelectric layer 1FL may be adjusted by controlling injection of the source gas into the chamber. The first ferroelectric layer 1FL may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc. according to the source gas used. The first ferroelectric layer 1FL may be formed of a material for which crystallization is possible.

In the deposition process for forming the first ferroelectric layer 1FL, the dopant concentration of the first ferroelectric layer 1FL may be changed by adjusting the content of dopants included in the source gas. A case where the first ferroelectric layer 1FL is formed of HfSiO₄(HSO) will be described as an example. HfO gas and Si gas may be used as source gases. The HfO gas may be supplied into the chamber for one cycle, and then the Si gas may be supplied into the chamber for one cycle. The Si gas may be used for dopants, and, therefore, the content of dopants included in the first ferroelectric layer 1FL may be changed by adjusting the supply amount of the Si gas.

Referring to FIG. 8D, when the first ferroelectric layer 1FL is formed to a target thickness, a crystallization process for crystallizing the first ferroelectric layer 1FL may be performed. For example, the crystallization process may be an annealing process. While the crystallization process is performed, the supply of the source gas may be suspended. The temperature and duration of the crystallization process may be adjusted according to the thickness of the first ferroelectric layer 1FL.

Referring to FIG. 8E, a deposition process for forming a second ferroelectric layer 2FL along the inner side surface of the crystallized first ferroelectric layer 1FL may be performed. For example, the source gas that was suspended for the crystallization process may again be supplied into the chamber so that the second ferroelectric layer 2FL may be formed. The deposition process for forming the second ferroelectric layer 2FL may be the ALD or ASD process. A thickness of the second ferroelectric layer 2FL may be determined according to how long the source gas is injected into the chamber. The second ferroelectric layer 2FL may be formed of the same material as the first ferroelectric layer 1FL, or it may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc.

Referring to FIG. 8F, when the second ferroelectric layer 2FL is formed to a target thickness, the crystallization process for crystallizing the second ferroelectric layer 2FL may be performed. For example, the crystallization process may be an annealing process. While the crystallization process is performed, the supply of the source gas may be suspended. The temperature and duration of the crystallization process may be adjusted according to the thickness of the second ferroelectric layer 2FL.

Referring to FIG. 8G, third and fourth ferroelectric layers 3FL and 4FL may be similarly formed along the inner side surface of the second ferroelectric layer 2FL. For example, the third and fourth ferroelectric layers 3FL and 4FL may be formed by repeating crystallization and deposition processes as described above after the second ferroelectric layer 2FL is formed. Accordingly, each of the first to fourth ferroelectric layers 1FL to 4FL may include crystallized grains. Although a case where the first to fourth ferroelectric layers 1FL to 4FL constitute a data storage layer DL is illustrated in FIG. 8G, the number of ferroelectric layers included in the data storage layer DL may be changed. For example, the data storage layer DL may include at least two ferroelectric layers.

As described above, first to fourth deposition and crystallization processes are repeatedly performed, so that grains can be formed in each of the first to fourth ferroelectric layers 1FL to 4FL.

Referring to FIG. 8H, a channel layer CHL and a core pillar CP may be formed inside the vertical hole HL in which the data storage layer DL is formed. The channel layer CHL may be formed of a conductive layer or a metal layer. For example, the channel layer CHL may be formed of silicon or poly-silicon. Because the channel layer CHL is formed of a conductive layer, dopants may be included in the channel layer CHL. For example, at least one dopant such as, for example, boron (B), phosphorus (P), arsenic (As), etc. may be included inside the channel layer CHL. In addition, various other dopants that can be used in a semiconductor may be used for the channel layer CHL. The core pillar CP may be formed of an insulating layer or a conductive layer. The first to fourth ferroelectric layers 1FL to 4FL and the channel layer CHL may be formed in a cylindrical shape, and the core pillar CP may be formed in a cylindrical pillar shape along the inner wall of the channel layer CHL. The core pillar CP may be formed of an insulating layer. However, the core pillar CP may be formed of a conductive layer for other embodiments of a memory device.

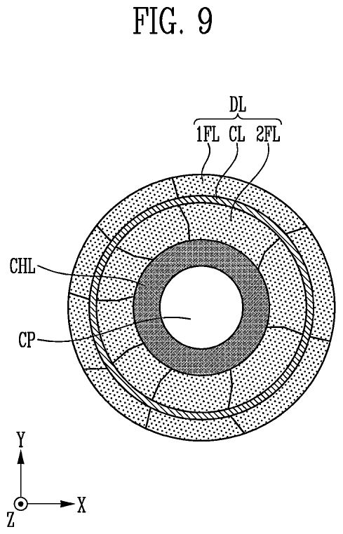

FIG. 9 is a view illustrating a structure of an example memory device in accordance with a second embodiment of the present disclosure.

Referring to FIG. 9, a data storage layer DL may include first and second ferroelectric layers 1FL and 2FL, and a crystal control layer CL. For example, the crystal control layer CL may be formed between the first and second ferroelectric layers 1FL and 2FL such that each of the first and second ferroelectric layers 1FL and 2FL are adjacent to the crystal control layer CL. The crystal control layer CL may be formed along the inner side surface of the first ferroelectric layer 1FL, and the second ferroelectric layer 2FL may be formed along the inner side surface of the crystal control layer CL. The crystal control layer CL may be formed to prevent the size of the grains of the first ferroelectric layer 1FL from increasing. The crystal control layer CL may be formed of an amorphous insulating layer such as, for example, an amorphous silicon oxide layer (a-SiO_{y}), an amorphous aluminum oxide layer (a-AlOₓ), etc. Here, x and y may be positive integers equal to or different from each other.

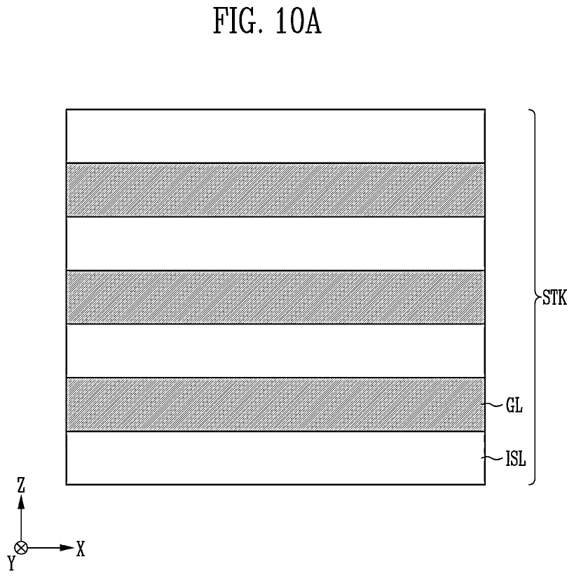

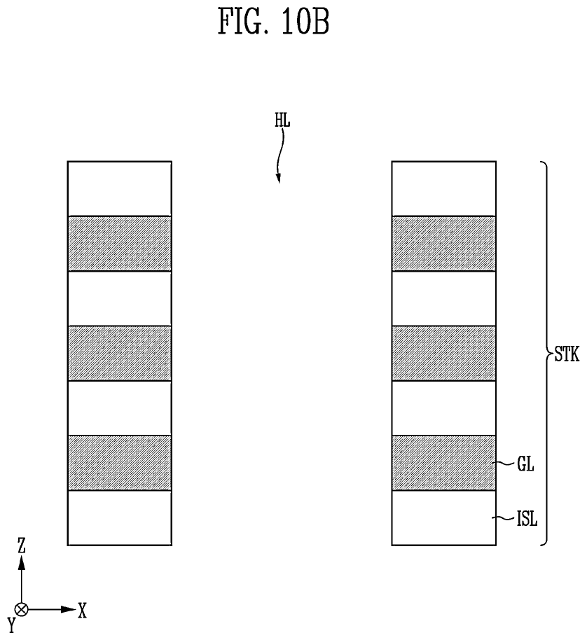

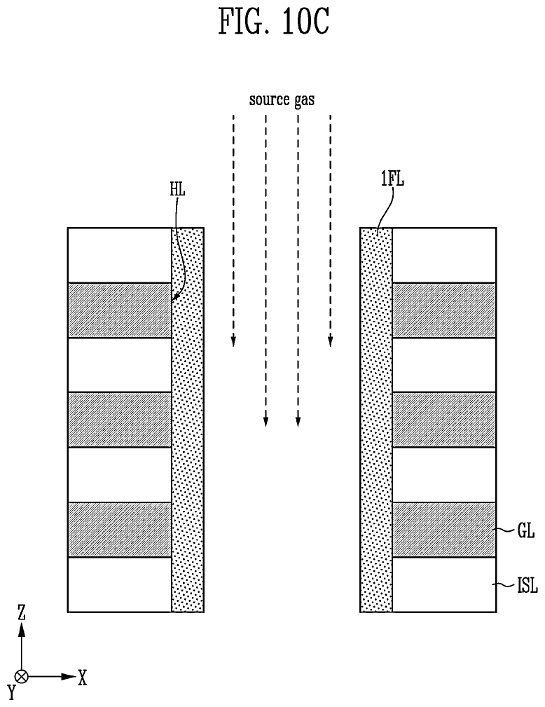

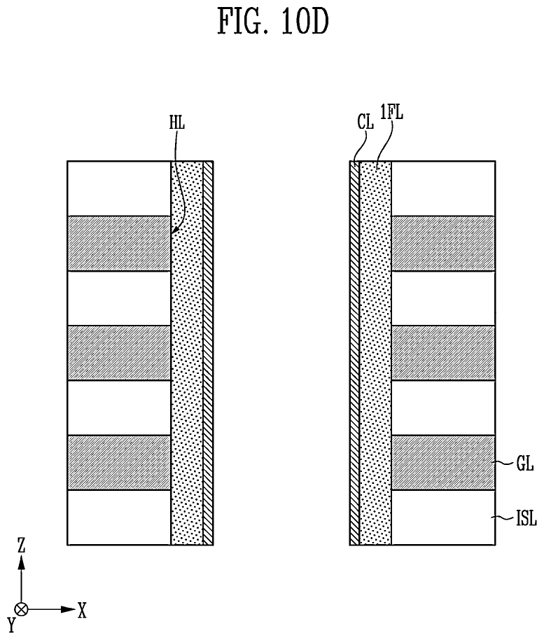

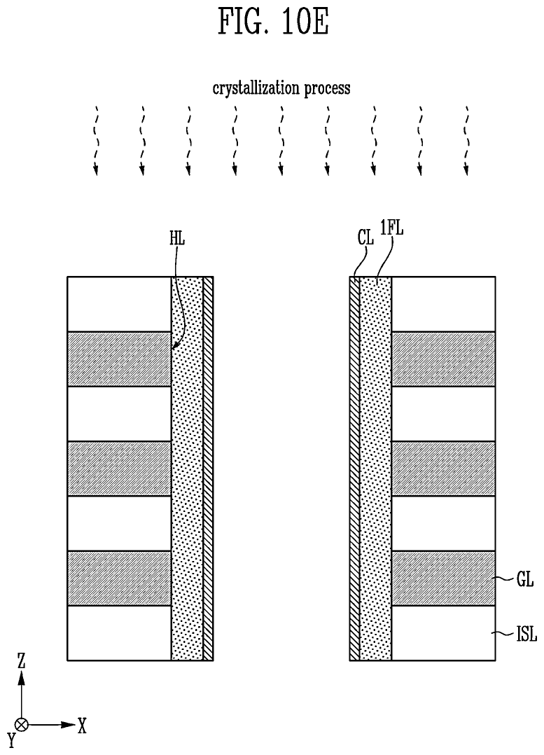

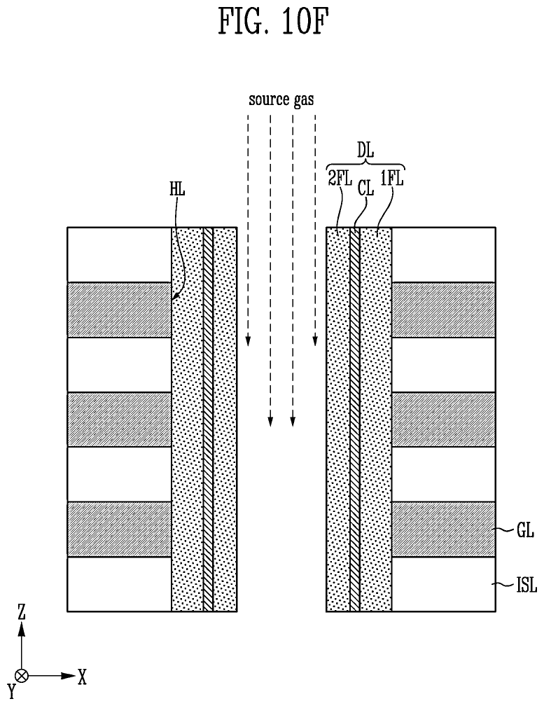

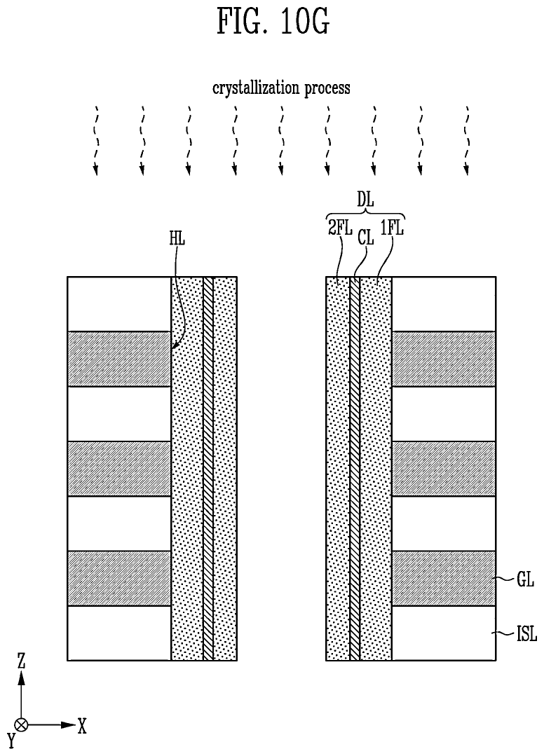

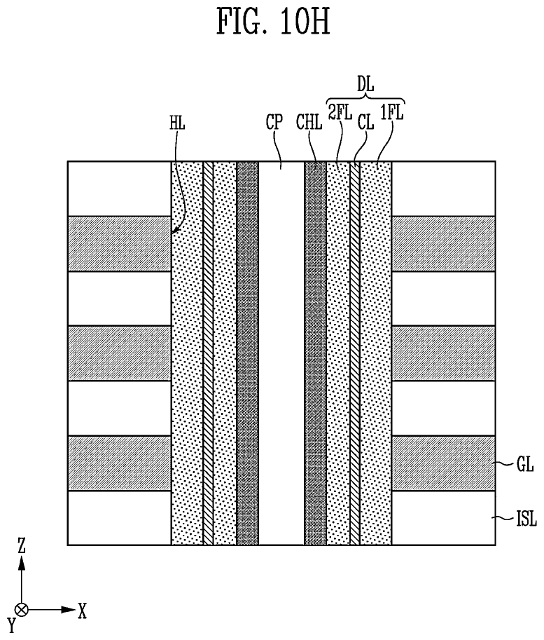

FIGS. 10A to 10H are views illustrating a manufacturing method of the example memory device in accordance with the second embodiment of the present disclosure.

Referring to FIG. 10A, a stack structure STK may be provided with interlayer insulating layers ISL and gate lines GL alternately stacked. Although not shown in the drawing, the stack structure STK may be formed on top of a substrate or a peripheral circuit structure that includes the substrate. The interlayer insulating layers ISL may be configured to block electrical connection between the gate lines GL, and may be formed of insulating material such as, for example, an oxide layer or a silicon oxide layer. The gate lines GL may be formed of a conductive layer or a metal layer. The gate lines GL may be formed of any one or more of conductive material such as, for example, tungsten (W), cobalt (Co), nickel (Ni), molybdenum (Mo), silicon (Si), poly silicon (poly-Si), etc.

Referring to FIG. 10B, an etching process may be performed to form a vertical hole HL vertically penetrating the interlayer insulating layers ISL and the gate lines GL. The etching process may be a dry etching process such as, for example, an anisotropic dry etching process. When the vertical hole HL is formed, at least some or all of the interlayer insulating layers ISL and the gate lines GL may be exposed through the side surface of the vertical hole HL.

Referring to FIG. 10C, a deposition process may form a first ferroelectric layer 1FL for data storage layer DL on the interlayer insulating layers ISL and the gate lines GL. The deposition process may be, for example, an Atomic Layer Deposition (ALD) process, an Area Selective Deposition (ASD) process, etc. In the ALD or ASD process, a thickness of a thin film may be determined according to how long a source gas is injected into a chamber. Therefore, the thickness of the first ferroelectric layer 1FL may be adjusted by controlling injection of the source gas into the chamber. The first ferroelectric layer 1FL may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc. according to the source gas used. The first ferroelectric layer 1FL may be formed of a material for which crystallization is possible. In the deposition process for forming the first ferroelectric layer 1FL, the dopant concentration of the first ferroelectric layer 1FL may be changed by adjusting the content of dopants included in the source gas.

Referring to FIG. 10D, when the first ferroelectric layer 1FL is formed to a target thickness, a deposition process for forming a crystal control layer CL along the inner side surface of the first ferroelectric layer 1FL may be performed. The crystal control layer CL may be formed to prevent the size of the grains of the first ferroelectric layer 1FL from increasing in a crystallization process performed subsequently. The crystal control layer CL may be formed of an amorphous insulating layer such as, for example, an amorphous silicon oxide layer (a-SiO_{y}), an amorphous aluminum oxide layer (a-AlOₓ), etc. Here, x and y may be positive integers equal to or different from each other.

Referring to FIG. 10E, a crystallization process for crystallizing the first ferroelectric layer 1FL may be performed. For example, the crystallization process may be an annealing process. While the crystallization process is performed, the supply of the source gas may be suspended. The temperature and duration of the crystallization process may be adjusted according to the thickness of the first ferroelectric layer 1FL. In the crystallization process, the amorphous crystal control layer CL is formed on the inner side surface of the first ferroelectric layer 1FL, and thus the size of the grains of the first ferroelectric layer 1FL may be kept from growing larger by the crystal control layer CL.

Referring to FIG. 10F, a deposition process to form a second ferroelectric layer 2FL along the inner side surface of the crystal control layer CL may be performed. For example, the source gas that was suspended during the crystallization process may again be supplied into the chamber. The deposition process for forming the second ferroelectric layer 2FL may be, for example, the ALD or ASD process. A thickness of the second ferroelectric layer 2FL may be determined according to how long the source gas is injected into the chamber. The second ferroelectric layer 2FL may be formed of the same material as the first ferroelectric layer 1FL, or it may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc.

Referring to FIG. 10G, when the second ferroelectric layer 2FL is formed to a target thickness, a crystallization process for crystallizing the second ferroelectric layer 2FL may be performed. For example, the crystallization process may be an annealing process. While the crystallization process is performed, the supply of the source gas may be suspended. The temperature and duration of the crystallization process may be adjusted according to the thickness of the second ferroelectric layer 2FL. Accordingly, a data storage layer DL including the first ferroelectric layer 1FL, the crystal control layer CL, and the second ferroelectric layer 2FL may be formed.

Referring to FIG. 10H, a channel layer CHL and a core pillar CP may be formed inside the vertical hole HL. The channel layer CHL may be formed of a conductive layer or a metal layer. For example, the channel layer CHL may be formed of silicon or poly-silicon. Because the channel layer CHL is formed of a conductive layer, dopants may be included in the channel layer CHL. For example, at least one dopant such as, for example, boron (B), phosphorus (P), arsenic (As), etc. may be included inside the channel layer CHL. In addition, various other dopants that can be used in a semiconductor may be used for the channel layer CHL. The core pillar CP may be formed of an insulating layer or a conductive layer. The first and second ferroelectric layers 1FL and 2FL and the channel layer CHL may be formed in a cylindrical shape, and the core pillar CP may be formed in a cylindrical pillar shape along the inner wall of the channel layer CHL. The core pillar CP may be formed of an insulating layer. However, the core pillar CP may be formed of a conductive layer for other embodiments of a memory device.

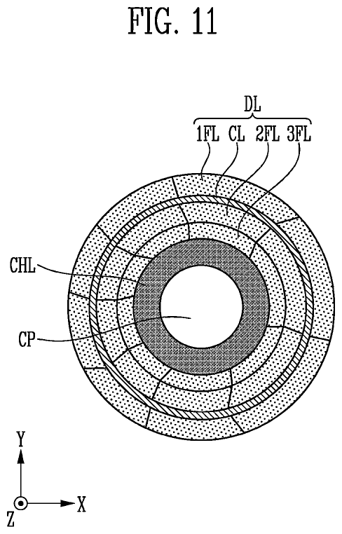

FIG. 11 is a view illustrating a structure of an example memory device in accordance with a third embodiment of the present disclosure.

Referring to FIG. 11, a data storage layer DL may include first to third ferroelectric layers 1FL to 3FL and a crystal control layer CL. For example, the crystal control layer CL may be formed between the first and second ferroelectric layers 1FL and 2FL, and the third ferroelectric layer 3FL may be in contact with the second ferroelectric layer 2FL. For example, the crystal control layer CL may be formed along the inner side surface of the first ferroelectric layer 1FL, the second ferroelectric layer 2FL may be formed along the inner side surface of the crystal control layer, and the third ferroelectric layer 3FL may be formed along the inner side surface of the second ferroelectric layer 2FL. The crystal control layer CL may be formed to prevent the size of the grains of the first ferroelectric layer 1FL from increasing. The crystal control layer CL may be formed of an amorphous insulating layer such as, for example, an amorphous silicon oxide layer (a-SiO_{y}), an amorphous aluminum oxide layer (a-AlOₓ), etc. Here, x and y may be positive integers equal to or different from each other.

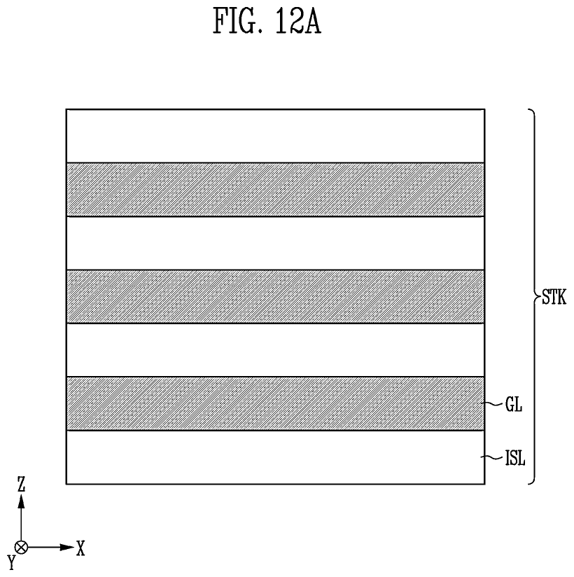

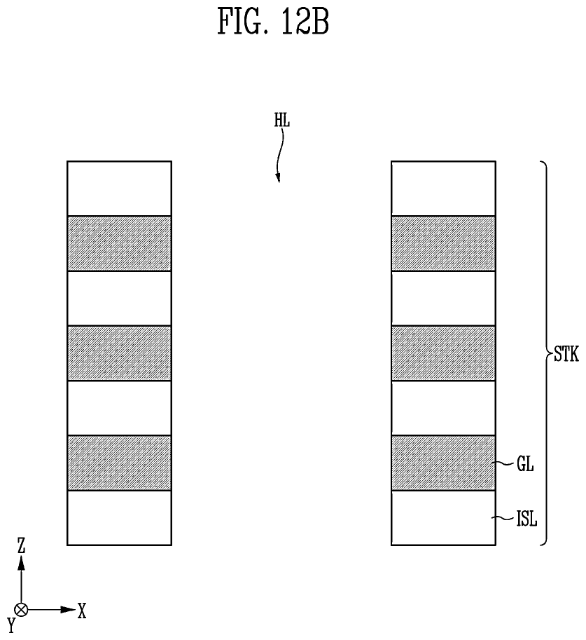

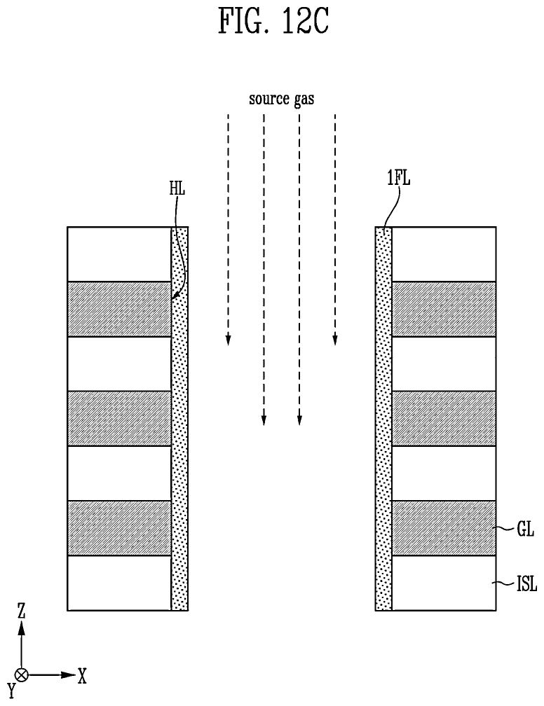

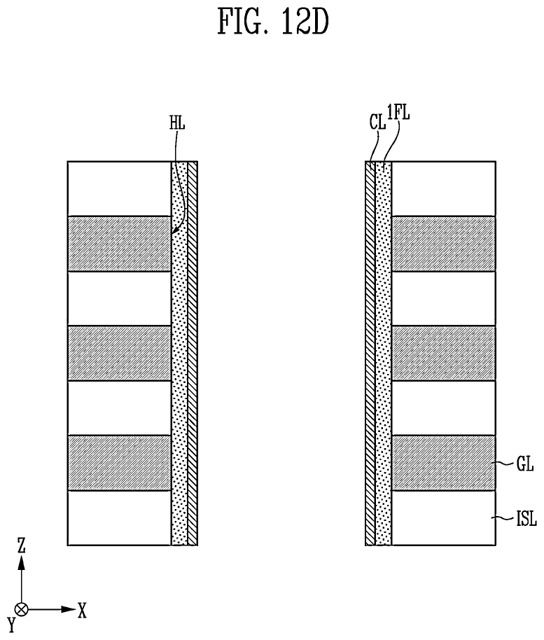

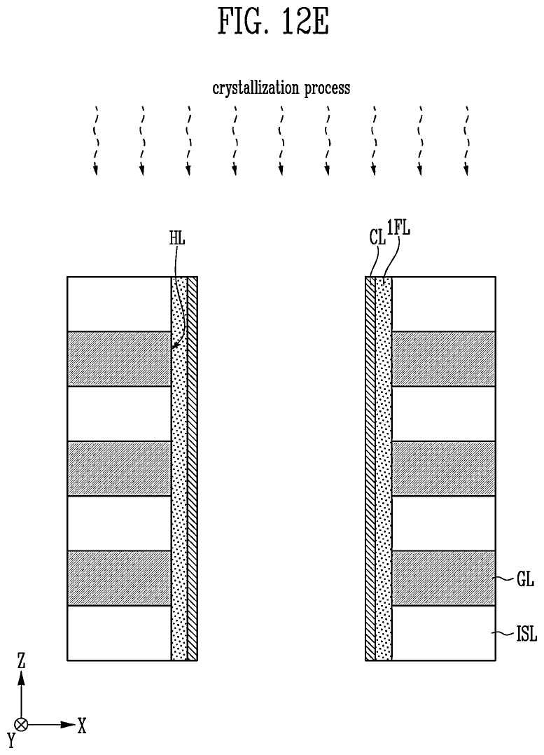

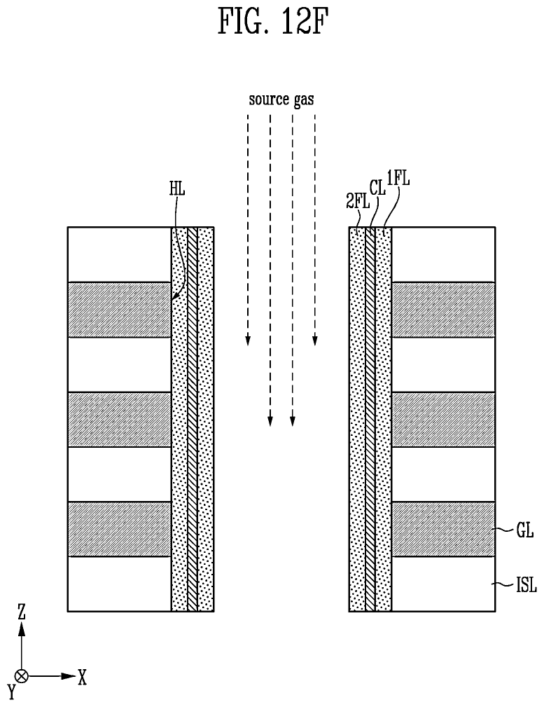

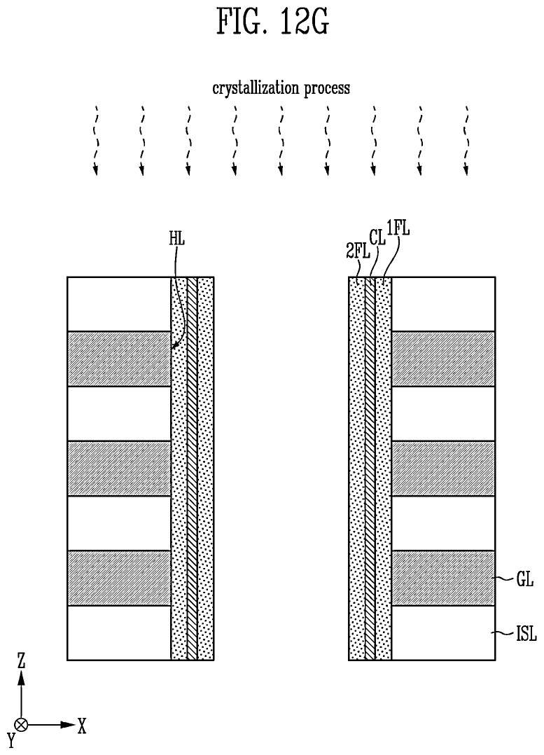

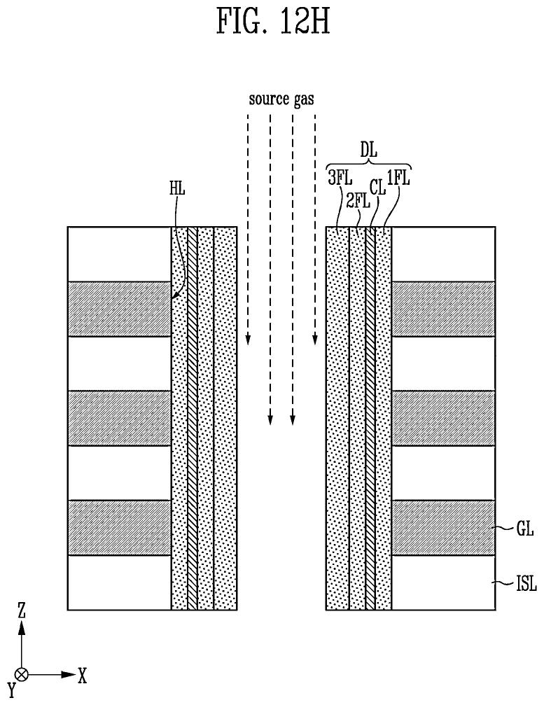

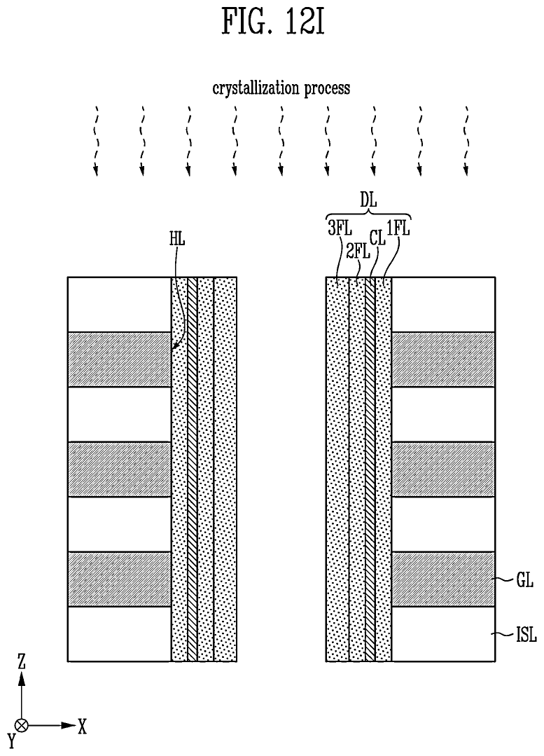

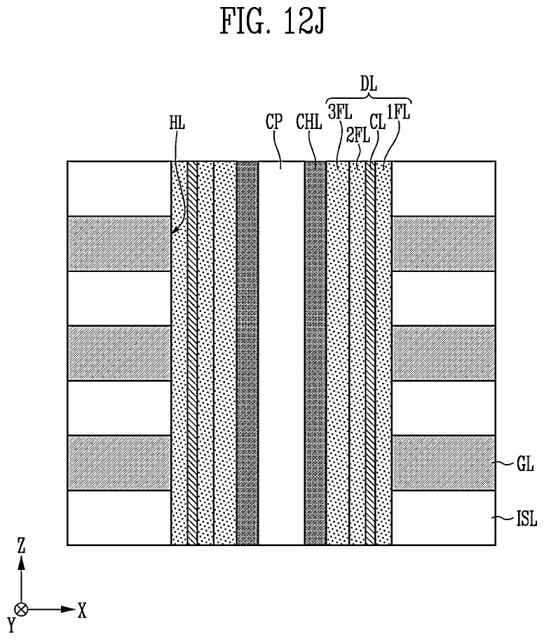

FIGS. 12A to 12J are views illustrating a manufacturing method of the example memory device in accordance with the third embodiment of the present disclosure.

Referring to FIG. 12A, a stack structure STK may be provided, in which interlayer insulating layers ISL and gate lines GL are alternately stacked. Although not shown in the drawing, the stack structure STK may be formed on top of a substrate or a peripheral circuit structure that includes the substrate. The interlayer insulating layers ISL may be configured to block electrical connection between the gate lines GL, and be formed of insulating material such as, for example, an oxide layer or a silicon oxide layer. The gate lines GL may be formed of a conductive layer or a metal layer. The gate lines GL may be formed of any one or more of conductive material such as, for example, tungsten (W), cobalt (Co), nickel (Ni), molybdenum (Mo), silicon (Si), poly silicon (poly-Si), etc.

Referring to FIG. 12B, an etching process for forming a vertical hole HL vertically penetrating the interlayer insulating layers ISL and the gate lines GL may be performed. The etching process may be a dry etching process such as, for example, an anisotropic dry etching process. When the vertical hole HL is formed, at least some or all of the interlayer insulating layers ISL and the gate lines GL may be exposed through the side surface of the vertical hole HL.

Referring to FIG. 12C, a deposition process may be performed to form a first ferroelectric layer 1FL for data storage layer DL on the interlayer insulating layers ISL and the gate lines GL. The deposition process may be, for example, an Atomic Layer Deposition (ALD) process, an Area Selective Deposition (ASD) process, etc. In the ALD or ASD process, the thickness of a layer may be determined according to how long a source gas is injected into a chamber, and therefore, the thickness of the first ferroelectric layer 1FL may be adjusted by controlling injection of the source gas into the chamber. The first ferroelectric layer 1FL may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc. according to the source gas used. The first ferroelectric layer 1FL may be formed of a material for which crystallization is possible. In the deposition process for forming the first ferroelectric layer 1FL, the dopant concentration of the first ferroelectric layer 1FL may be adjusted by adjusting the content of dopants included in the source gas.

Referring to FIG. 12D, when the first ferroelectric layer 1FL is formed to a target thickness, a deposition process may form a crystal control layer CL along the inner side surface of the first ferroelectric layer 1FL. The crystal control layer CL may be formed to prevent the size of the grains of the first ferroelectric layer 1FL from increasing. The crystal control layer CL may be formed of an amorphous insulating layer such as, for example, an amorphous silicon oxide layer (a-SiO_{y}), an amorphous aluminum oxide layer (a-AlOₓ), etc. Here, x and y may be positive integers equal to or different from each other.

Referring to FIG. 12E, a crystallization process for crystallizing the first ferroelectric layer 1FL may be performed. For example, the crystallization process may be an annealing process. While the crystallization process is performed, the supply of the source gas may be suspended. The temperature and duration of the crystallization process may be adjusted according to the thickness of the first ferroelectric layer 1FL. In the crystallization process, the amorphous crystal control layer CL is formed on the inner side surface of the first ferroelectric layer 1FL, and thus the increase in the size of the grains of the first ferroelectric layer 1FL can be suppressed by the crystal control layer CL.

Referring to FIG. 12F, a deposition process to form a second ferroelectric layer 2FL along the inner side surface of the crystal control layer CL may be performed. For example, the source gas suspended during the crystallization process may again be supplied into the chamber. The deposition process for forming the second ferroelectric layer 2FL may be, for example, the ALD or ASD process. A thickness of the second ferroelectric layer 2FL may be determined according to how long the source gas is injected into the chamber. The second ferroelectric layer 2FL may be formed of the same material as the first ferroelectric layer 1FL, or it may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc.

Referring to FIG. 12G, when the second ferroelectric layer 2FL is formed to a target thickness, a crystallization process for crystallizing the second ferroelectric layer 2FL may be performed. For example, the crystallization process may be an annealing process. While the crystallization process is performed, the supply of the source gas to form the second ferroelectric layer 2FL may be suspended. The temperature and duration of the crystallization process may be adjusted according to the thickness of the second ferroelectric layer 2FL.

Referring to FIG. 12H, a deposition process to form a third ferroelectric layer 3FL along the inner side surface of the second ferroelectric layer 2FL may be performed. For example, the source gas that was suspended during the crystallization process may again be supplied into the chamber. The deposition process for forming the third ferroelectric layer 3FL may be, for example, the ALD or ASD process. A thickness of the third ferroelectric layer 3FL may be determined according to how long the source gas is injected into the chamber. For example, the third ferroelectric layer 3FL may be formed of the same material as the first or second ferroelectric layer 1FL or 2FL, or it may be formed of at least one material such as, for example, PbZrTiO₃(PSZ), SrBi₂Ta₂O₉(STB), BiFeO₃(BFO), HfO₂, HfO₂ZrO₂(HZO), HfSiO₄(HSO), etc.

Referring to FIG. 12I, when the third ferroelectric layer 3FL is formed to a target thickness, a crystallization process for crystallizing the third ferroelectric layer 3FL may be performed. For example, the crystallization process may be an annealing process. While the crystallization process is performed, the supply of the source gas to form the third ferroelectric layer 3FL may be suspended. The temperature and duration of the crystallization process may be adjusted according to the thickness of the third ferroelectric layer 3FL. Accordingly, a data storage layer DL that includes the first ferroelectric layer 1FL, the crystal control layer CL, the second ferroelectric layer 2FL, and the third ferroelectric layer 3FL may be formed.

Referring to FIG. 12J, a channel layer CHL and a core pillar CP may be formed inside the vertical hole HL in which the data storage layer DL is formed. The channel layer CHL may be formed of a conductive layer or a metal layer. For example, the channel layer CHL may be formed of silicon or poly-silicon. Because the channel layer CHL is formed of a conductive layer, dopants may be included in the channel layer CHL. For example, at least one dopant such as, for example, boron (B), phosphorus (P), arsenic (As), etc. may be included inside the channel layer CHL. In addition, various other dopants that can be used in a semiconductor may be used for the channel layer CHL. The core pillar CP may be formed of an insulating layer or a conductive layer. The first to third ferroelectric layers 1FL to 3FL and the channel layer CHL may be formed in a cylindrical shape, and the core pillar CP may be formed in a cylindrical pillar shape along the inner wall of the channel layer CHL. The core pillar CP may be formed of an insulating layer. However, the core pillar CP may be formed of a conductive layer for other embodiments of a memory device.

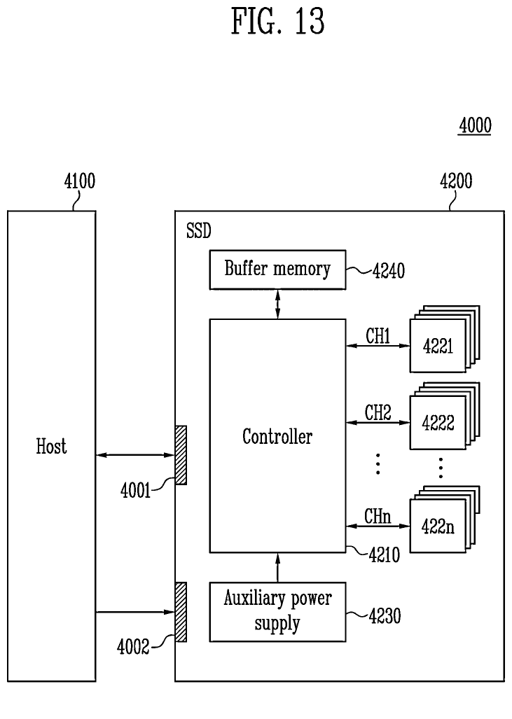

FIG. 13 is a diagram illustrating a Solid State Drive (SSD) system to which an example memory device of the present disclosure is applied.

Referring to FIG. 13, the SSD system 4000 includes a host 4100 and an SSD 4200. The SSD 4200 may exchange signals with the host 4100 through a signal connector 4001, and be supplied with power through a power connector 4002. The SSD 4200 includes a controller 4210, a plurality of FRAM devices 4221 to 422n, an auxiliary power supply 4230, and a buffer memory 4240.

In accordance with an embodiment of the present disclosure, each of the FRAM devices 4221 to 422n may be configured similarly to the memory device 1100 described with reference to FIG. 1.

The controller 4210 may control the FRAM devices 4221 to 422n in response to signals received from the host 4100. The signal may be transmitted via an interface between the host 4100 and the SSD 4200. The interface may be at least one of various interfaces such as, for example, Universal Serial Bus (USB), Multi-Media Card (MMC), embedded MMC (eMMC), Peripheral Component Interconnection (PCI), PCI express (PCIe), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), FIREWIRE, Universal Flash Storage (UFS), WI-FI, Bluetooth, NVMe, etc.

The auxiliary power supply 4230 may be connected to the host 4100 through the power connector 4002. The auxiliary power supply 4230 may receive power from the host 4100 for operation including charging the auxiliary power supply 4230. When power from the host 4100 is not within specification, the auxiliary power supply 4230 may provide power for the SSD 4200. The auxiliary power supply 4230 may be located in the SSD 4200 or outside of the SSD 4200. For example, the auxiliary power supply 4230 may be located on a main board, and provide auxiliary power to the SSD 4200.

The buffer memory 4240 may be used as a buffer memory of the SSD 4200. For example, the buffer memory 4240 may temporarily store data received from the host 4100 or data received from the plurality of FRAM devices 4221 to 422n, or temporarily store meta data (e.g., a mapping table) of the FRAM devices 4221 to 422n. The buffer memory 4240 may include volatile memories such as DRAM, SDRAM, DDR SDRAM, LPDDR SDRAM, GRAM, etc., or nonvolatile memories such as FRAM, ReRAM, STT-MRAM, PRAM, etc.

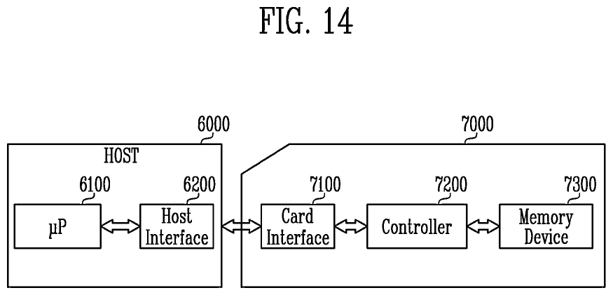

FIG. 14 is a diagram illustrating a memory card system to which an example memory device of the present disclosure is applied.

Referring to FIG. 14, the memory card system 7000 may be implemented as a memory card or a smart card. The memory system 7000 may include a memory device 7300, a controller 7200, and a card interface 7100.

The memory device 7300 may be configured similarly to the memory device 1100 shown in FIG. 1.

The controller 7200 may control data exchange between the memory device 7300 and the card interface 7100. In some embodiments, the card interface 7100 may be a secure digital (SD) card interface or a multi-media card (MMC) interface, but the present disclosure is not limited thereto.

The card interface 7100 may interface for data exchange between a host 6000 and the controller 7200 according to a protocol of the host 6000. In some embodiments, the card interface 7100 may support universal serial bus (USB) protocol and an inter-chip (IC)-USB protocol. The card interface 7100 may use hardware circuits and/or software to support the protocol used by the host 6000.

When the memory system 7000 is connected to a host interface 6200 of the host 6000, where the host may be a device such as, for example, a PC, a tablet PC, a digital camera, a digital audio player, a cellular phone, console video game hardware, a digital set-top box, etc., the host interface 6200 may perform data communication with the memory device 7300 through the card interface 7100 and the controller 7200 under the control of a microprocessor (riP) 6100. The microprocessor 6100 may be a device capable of executing software.

In accordance with the present disclosure, the threshold voltage distribution of a memory device with FRAM cells can be improved.

While the present disclosure has been shown and described with reference to certain embodiments, it will be understood by those skilled in the art that various changes in form and details may be made therein without departing from the spirit and scope of the present disclosure as explained and illustrated in the specification and drawings, and defined by the appended claims and their equivalents. Therefore, the scope of the present disclosure should not be limited to just the above-described embodiments and/or the listed claims.

In the above-described embodiments, all steps may be performed as described, or part of the steps and may be omitted or additional steps added. For example, there may be additional layers, whether dummy layers or not, between an interlayer insulating layer ISL and a gate line GL. In an embodiment, the steps need not necessarily be performed in the described order, and the steps may be rearranged. In another example, an embodiment may comprise a first stack structure on a first substrate, a second substrate on the first stack structure, and a second stack structure on the second substrate. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

The embodiments of the present disclosure have been described in the drawings and specification. The present disclosure is not restricted to the above-described embodiments. Many variations may be possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a stack structure comprising interlayer insulating layers and gate lines alternately stacked with each other;
a data storage layer vertically penetrating the stack structure, the data storage layer including a plurality of ferroelectric layers; and
a channel layer surrounded by the data storage layer.

2. The memory device of claim 1, wherein the plurality of ferroelectric layers are formed of at least one material among PbZrTiO₃(PSZ), SrBi₂Ta₂O₉(STB), BiFeO₃(BFO), HfO₂, HfO₂ZrO₂(HZO), and HfSiO₄(HSO).

3. The memory device of claim 1, wherein the plurality of ferroelectric layers:
includes a first ferroelectric layer that vertically penetrates the stack structure and has a cylindrical shape; and
one or more ferroelectric layers sequentially formed in a cylindrical shape along an inner wall of the first ferroelectric layer.

4. The memory device of claim 1, further comprising a crystal control layer formed between two ferroelectric layers of the plurality of ferroelectric layers.

5. The memory device of claim 4, wherein the crystal control layer is formed of an amorphous insulating layer.

6. The memory device of claim 4, wherein the crystal control layer is formed of an amorphous silicon oxide layer or an amorphous aluminum oxide layer.

7. A method of manufacturing a memory device, the method comprising:
alternately stacking interlayer insulating layers and gate lines on a lower structure;
forming a vertical hole penetrating the interlayer insulating layers and the gate lines, wherein side surfaces of the interlayer insulating layers and the gate lines are exposed;
forming a data storage layer including a plurality of ferroelectric layers in the vertical hole along the side surfaces of the interlayer insulating layers and the gate lines; and
forming a channel layer along an inner side surface of the data storage layer.

8. The method of claim 7, wherein each of the plurality of ferroelectric layers is formed of at least one material among PbZrTiO3(PSZ), SrBi2Ta2O9(STB), BiFeO3(BFO), HfO2, HfO2ZrO2(HZO), and HfSiO4(HSO).

9. The method of claim 7, wherein forming the data storage layer including the plurality of ferroelectric layers includes:
forming a first ferroelectric layer along the side surfaces of the interlayer insulating layers and the gate lines;
performing a first crystallization process to crystallize the first ferroelectric layer;
forming a second ferroelectric layer along a side surface of the crystallized first ferroelectric layer; and
performing a second crystallization process to crystallize the second ferroelectric layer.

10. The method of claim 9, wherein forming the data storage layer including the plurality of ferroelectric layers includes sequentially forming one or more ferroelectric layers on the second ferroelectric layer.

11. The method of claim 9, wherein forming one or both of the first ferroelectric layer and the second ferroelectric layer is performed through an Atomic Layer Deposition (ALD) process or an Area Selective Deposition (ASD) process.

12. The method of claim 9, wherein one or both of the first and second crystallization processes are performed as an annealing process.

13. The method of claim 12, wherein:
first grains are formed in the first ferroelectric layer through the first crystallization process, and
second grains are formed in the second ferroelectric layer through the second crystallization process.

14. A method of manufacturing a memory device, the method comprising:
alternately stacking interlayer insulating layers and gate lines on a lower structure;
forming a vertical hole exposing side surfaces of the interlayer insulating layers and the gate lines while penetrating the interlayer insulating layers and the gate lines;
forming a first ferroelectric layer along the exposed side surfaces of the interlayer insulating layers and the gate lines;
forming a crystal control layer along an inner side surface of the first ferroelectric layer;
performing a first crystallization process to crystallize the first ferroelectric layer;
forming a second ferroelectric layer along an inner side surface of the crystal control layer;
performing a second crystallization process to crystallize the second ferroelectric layer; and
forming a channel layer in a region surrounded by the crystallized second ferroelectric layer.

15. The method of claim 14, wherein the crystal control layer is formed of an amorphous insulating layer.

16. The method of claim 14, wherein the crystal control layer is formed of an amorphous silicon oxide layer or an amorphous aluminum oxide layer.

17. The method of claim 14, wherein each of the first ferroelectric layer and the second ferroelectric layer is formed of at least one material among PbZrTiO3(PSZ), SrBi2Ta2O9(STB), BiFeO3(BFO), HfO2, HfO2ZrO2(HZO), and HfSiO4(HSO).

18. The method of claim 14, wherein the crystallization process is performed as an annealing process.

19. The method of claim 14, further comprising:
after performing the second crystallization process,
forming a third ferroelectric layer along an inner side surface of the crystallized second ferroelectric layer; and
performing a third crystallization process for crystallizing the third ferroelectric layer.

20. The method of claim 14, further comprising forming a core pillar along an inner side surface of the channel layer.
